(19) United States
(12) Patent Application Publication
(10) Pub. No.: US 2013/0043559 A1
(43) Pub. Date: Feb. 21, 2013

(54) TRENCH FORMATION IN SUBSTRATE

(71) Applicants: JUNEDONG LEE, Hopewell Junction, NY (US); Xi Li, Somers, NY (US); Paul C. Parries, Wappingers Falls, NY (US); Richard Wise, Newburgh, NY (US); Hongwen Yan, Somers, NY (US)

(72) Inventors: JUNEDONG LEE, Hopewell Junction, NY (US); Xi Li, Somers, NY (US); Paul C. Parries, Wappingers Falls, NY (US); Richard Wise, Newburgh, NY (US); Hongwen Yan, Somers, NY (US)

(73) Assignee: International Business Machines Corporation, Armonk, NY (US)

(21) Appl. No.: 13/211,570

(22) Filed: Aug. 17, 2011

(51) Int. Cl. H01L 21/20; H01L 29/92; H01L 21/28

(52) U.S. Cl. 257/532; 438/666; 438/386; 257/E21.158; 257/E21.09; 257/E29.343

(57) ABSTRACT

A method includes removing an exposed portion of a first portion of a substrate to define a first trench portion partially defined by the first portion of the substrate and expose a second portion of the substrate, the first portion of the substrate disposed on the second portion of the substrate, the second portion of the substrate including an N+ doped silicon material, and removing a portion the exposed second portion of the substrate with an isotropic etching process to define a second trench portion.

### BACKGROUND

The present invention relates to trench formation in a substrate, and more specifically, to the formation of trenches that may be used to form trench capacitors in a substrate.

Substrates may include a silicon layer that includes N+ type dopants. A buried oxide layer (BOX), silicon on insulator (SOI) layer, silicon nitride layer, and oxide layer may be disposed on the silicon layer.

Trenches may be formed in the substrate layers to form features on or in the substrate. The trenches may be filled with a conductive material to define capacitors or other devices.

### BRIEF SUMMARY

According to one embodiment of the present invention, a method includes removing an exposed portion of a first portion of a substrate to define a first trench portion partially defined by the first portion of the substrate and expose a second portion of the substrate, the first portion of the substrate disposed on the second portion of the substrate, the second portion of the substrate including an N+ doped silicon material, and removing a portion the exposed second portion of the substrate with an isotropic etching process to define a second trench portion.

According to another embodiment of the present invention, a method for forming a capacitor device includes removing an exposed portion of a first portion of a substrate to define a first trench portion of a first trench and a first trench portion of a second trench, the first trench portions partially defined by the first portion of the substrate and expose a second portion of the substrate, the first portion of the substrate disposed on the second portion of the substrate, the second portion of the substrate including an N+ doped silicon material, removing a portion the exposed second portion of the substrate with an isotropic etching process to define a second trench portion of the first trench and a second trench portion of the second trench, disposing a conductive material in the second trench portion of the first trench and the second trench portion of the second trench.

According to another embodiment of the present invention, a capacitor device includes a first trench having a first trench portion partially defined by a first portion of a substrate and a second trench portion partially defined by a second portion of the substrate, the first portion of the substrate including a silicon material layer and the second portion of the substrate including a N+ silicon material, the first trench portion having a substantially uniform width, the second trench portion having a tapered profile, a width of a portion of the second trench portion is greater than the width of the first trench portion, a second trench arranged substantially parallel to the first trench, the second trench having a first trench portion partially defined by the first portion of the substrate and a second trench portion partially defined by the second portion of the substrate, the first trench portion of the second trench having a substantially uniform width, the second trench portion of the second trench having a tapered profile, a width of a portion of the second trench portion of the second trench is greater than the width of the first trench portion of the second trench, and a conductive material disposed in the second trench portions of the first trench and the second trench.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a side cut-away view of a prior art example of a substrate.

FIG. 2 illustrates a prior art example of the formation of a portion of trenches in the substrate of FIG. 1.

FIG. 3 illustrates a prior art example of the further formation of the trenches in the substrate of FIG. 1.

FIG. 4 illustrates a side cut-away view of an exemplary embodiment of a substrate.

FIG. 5 illustrates the formation of first trench portions in the substrate of FIG. 4.

FIG. 6 illustrates the formation of second trench portions in the substrate of FIG. 4.

FIG. 7 illustrates a portion of a resultant capacitor following the deposition of a conductive material in the trench portions of FIG. 6.

### DETAILED DESCRIPTION

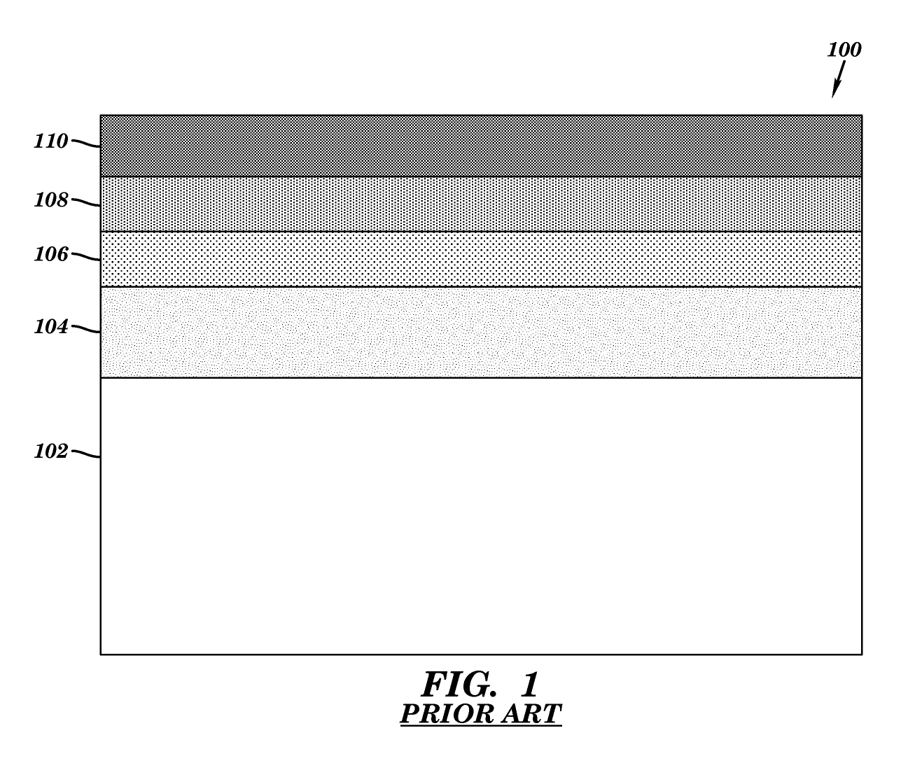

FIGS. 1-3 illustrate a side cut-away view of a prior art method for fabricating a trench capacitor in a substrate. Referring to FIG. 1, a substrate 100 includes a silicon layer 102 that includes N+Si material. A buried oxide (BOX) layer 104 is disposed on the silicon layer 102; a silicon on insulator (SOI) layer 106 is disposed on the BOX layer 104; a silicon nitride (SiN) layer 108 is disposed on the SOI layer 106, and an oxide layer 110 is disposed on the SiN layer 108.

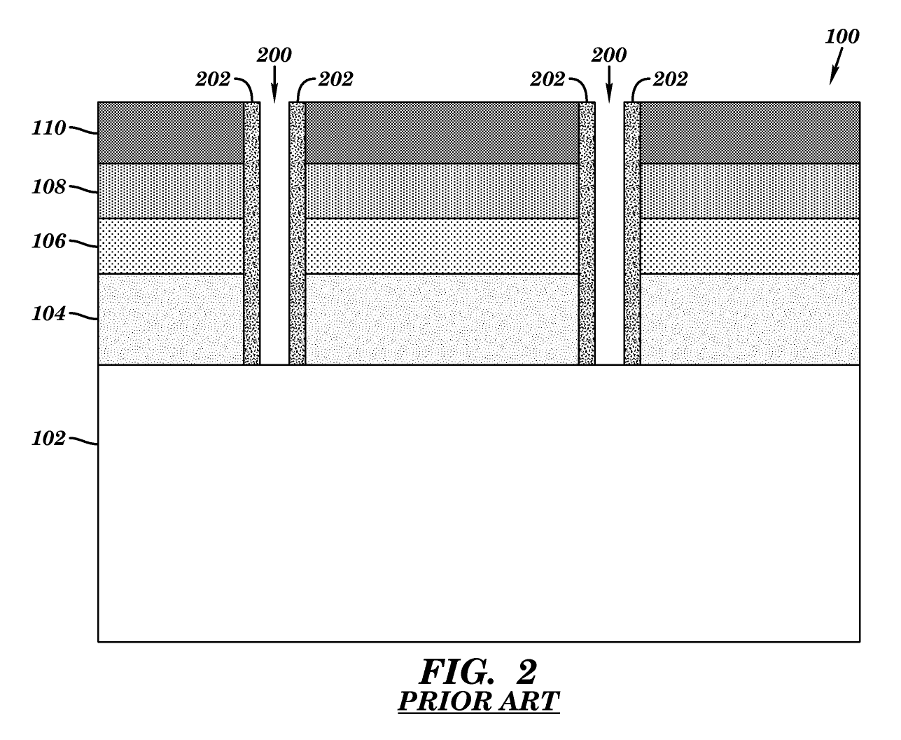

FIG. 2 illustrates the formation of a portion of trenches 200 that are formed by a lithographic masking and anisotropic etching process such as reactive ion etching (RIE). The etching process removes exposed portions of the oxide layer 110, the SiN layer 108, the SOI layer 106, and the BOX layer 104 to expose portions of the silicon layer 102. Following the formation of the trenches 200, spacers 202 formed from SiN material are formed along the exposed sidewalls of the trenches 200.

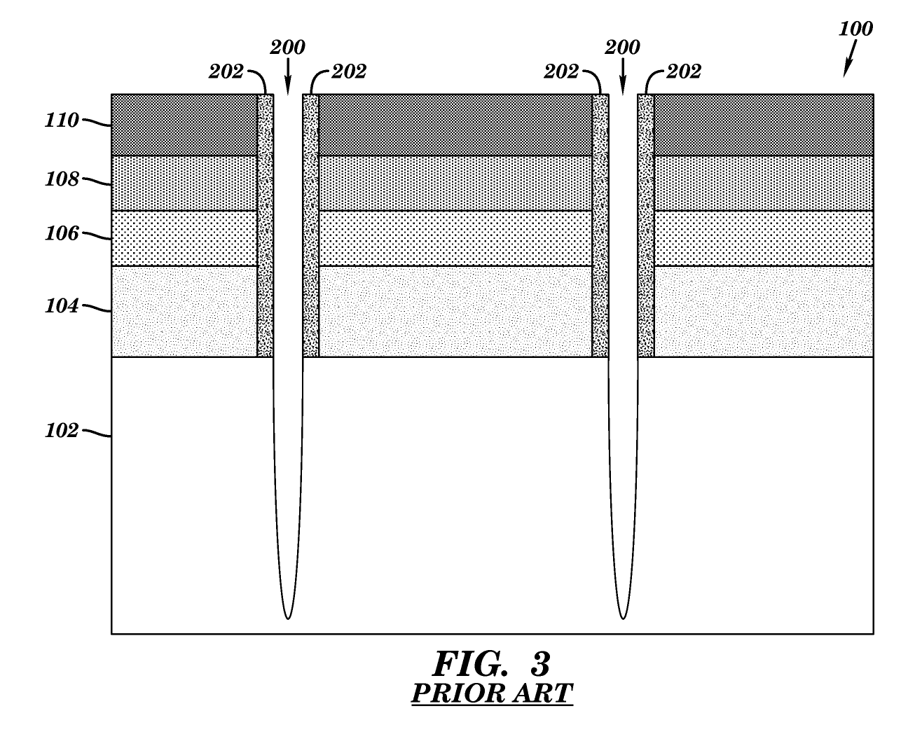

FIG. 3 illustrates the further formation of the trenches 200 in the silicon layer 102. The trenches 200 are further formed by removing portions of the silicon layer 102 by using a wet etching process that selectively removes Oxide and SiN. The spacers 202 protect the SOI layer 106 so that the etching process does not remove material from the SOI layer 106. Following the formation of the trenches 200, a conductive material (not shown) may be disposed in the trenches 200 to form a capacitive device.

The prior art method described above for forming trenches uses spacers 202 to prevent material from the SOI layer 106 from being removed when etching the silicon layer 102. A disadvantage of using the spacers 202 is that when the scale and pitch (i.e., ratio of width to depth) of the trenches decreases, the width of the spacers remains constant and obscures a larger portion of the silicon layer 102. The subsequent etching process that removes the exposed portions of the silicon layer 102 may not reach a sufficient depth to form a trench having a desired depth. Increasing the width of the trench formed in the layers above the silicon layer 102 prior to forming the spacers 202 may expose a sufficient area of the silicon layer 102 for etching, however the distance between the trenches in the silicon layer 102 is then undesirably increased.

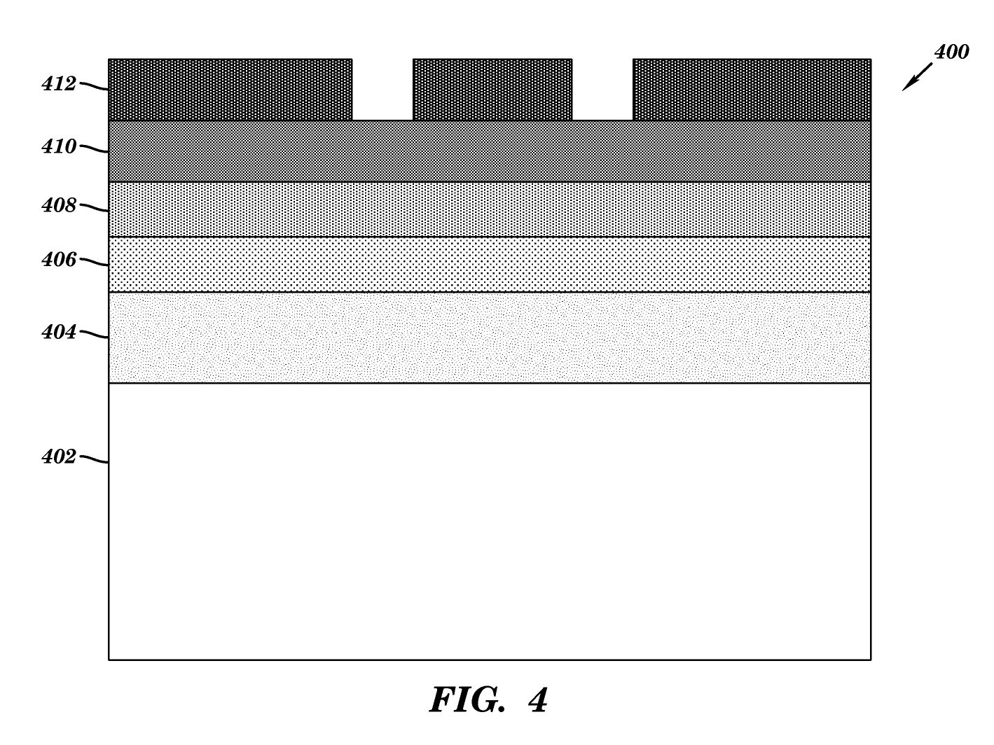

FIGS. 4-7 illustrate a side cut-away view of an exemplary method for forming trenches and resultant trench arrangement embodiment. Referring to FIG. 4, a substrate 400 includes a silicon layer 402 that includes N+Si material. A buried oxide (BOX) layer 404 is disposed on the silicon layer 402; a silicon on insulator (SOI) layer 406 is disposed on the BOX layer 404; a silicon nitride (SiN) layer 408 is disposed on the SOI layer 406, and an oxide layer 410 is disposed on the SiN layer 408. Though the illustrated embodiment includes a number of different layers of various materials disposed on the silicon layer 402, alternate embodiments may include any combination of any number of alternate materials. The silicon layer 402 includes N+Si material that may be formed by, for example, implanting N+ ions in the silicon layer 402 or epitaxially growing the silicon layer 402 while in situ doping the silicon layer 402 during the epitaxial growth process.

In the illustrated embodiment a lithographic masking material 412 is patterned over the oxide layer 410.

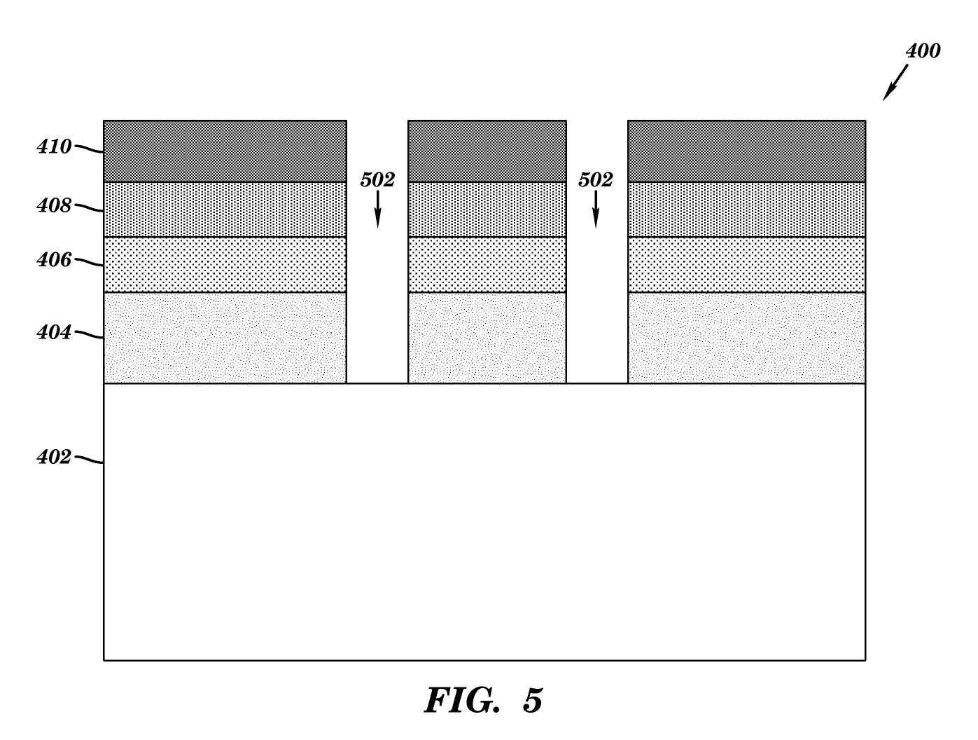

FIG. 5 illustrates the formation of first trench portions 502. The first trench portions 502 are formed by an anisotropic etching process such as, for example, low pressure reactive ion etching (RIE). The etching process removes exposed portions of the oxide layer 410, the SiN layer 408, the SOI layer 406, and the BOX layer 404 to expose portions of the silicon layer 402. Following the exposure of portions of the silicon layer 402, a wet clean process may be performed to remove polymer materials.

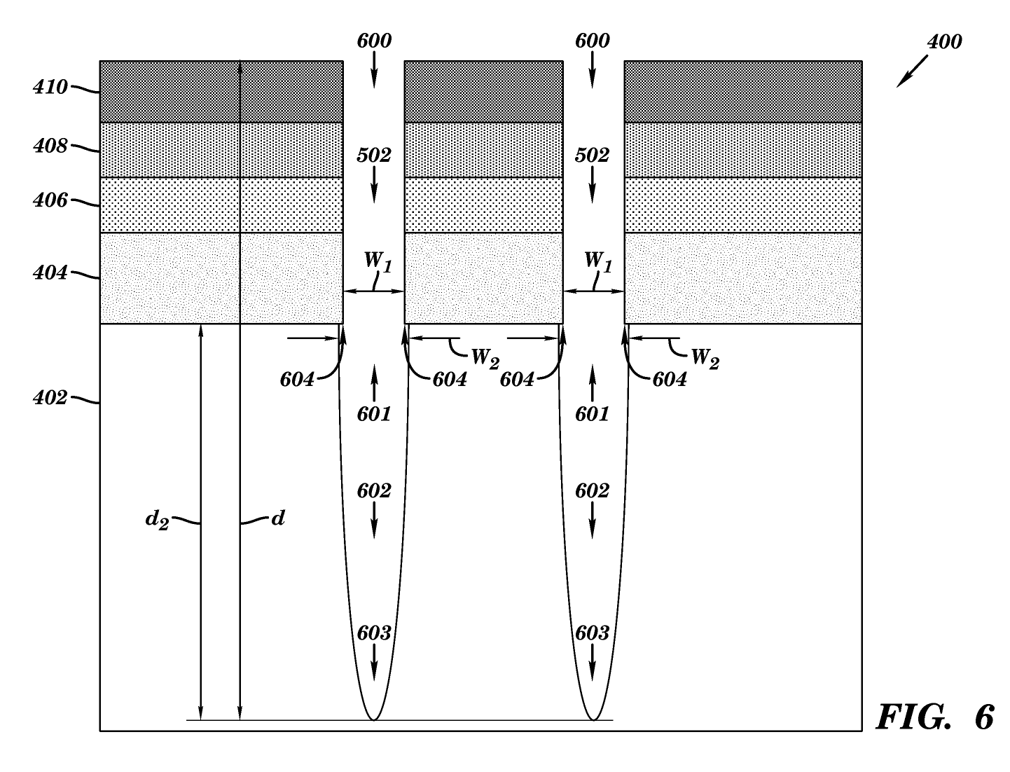

FIG. 6 illustrates the formation of second trench portions 602 resulting in the trenches 600. The second trench portions are formed by an isotropic etching process that is selective to etch the N+ silicon material of the silicon layer 402. The isotropic etching process does not appreciably remove silicon in the SOI layer 406, the BOX layer 404, or the SiN layer 408. In this regard, the etching process includes a transformer coupled plasma (TCP) or an inductively coupled plasma (ICP) etching process using Cl₂/He etch chemistry in a ratio of about 1:1. The range of chamber pressures is about 50-200 millitorr, and the range of chamber temperatures is about 50-70° C. The power ranges between 700-1200 W. In the exemplary TCP or ICP processes, the plasma generation is to some extent due to capacitive coupling of radio frequency power from the induction coil to the plasma. ICP or TCP excited by radio frequency fields generated by various different coil geometries produce high ion densities, at low pressures. The exemplary etching process has very high selectivity to oxide, SiN and Si during N+Si Cl2/He etch. The selectivity is about 20:1 for Si and about 100:1 for Oxide and SiN.

The isotropic etching process forms the second trench portions 602 such that a resultant desired width (W) of the trenches 600 is achieved, where the second trench portion has a width (W₂). Since the etching process that forms the second trench portions 602 is isotropic, the width (W₂) of the trench portions 602 is increased during the etch, and is greater than the width (W₁) of the first trench portions 502 in the upper regions 601 of the second trench portions 602, and tapers to a lesser width in the lower regions 603 of the second trench portions 602. The difference between the widths W1 and W2 results in undercut regions 604 defined by the substantially vertical walls and substantially horizontal bottom portion of the BOX layer that is disposed on the silicon layer 402, and the silicon layer 402. Following the formation of the second trench portion 602, a wet cleaning process may be performed.

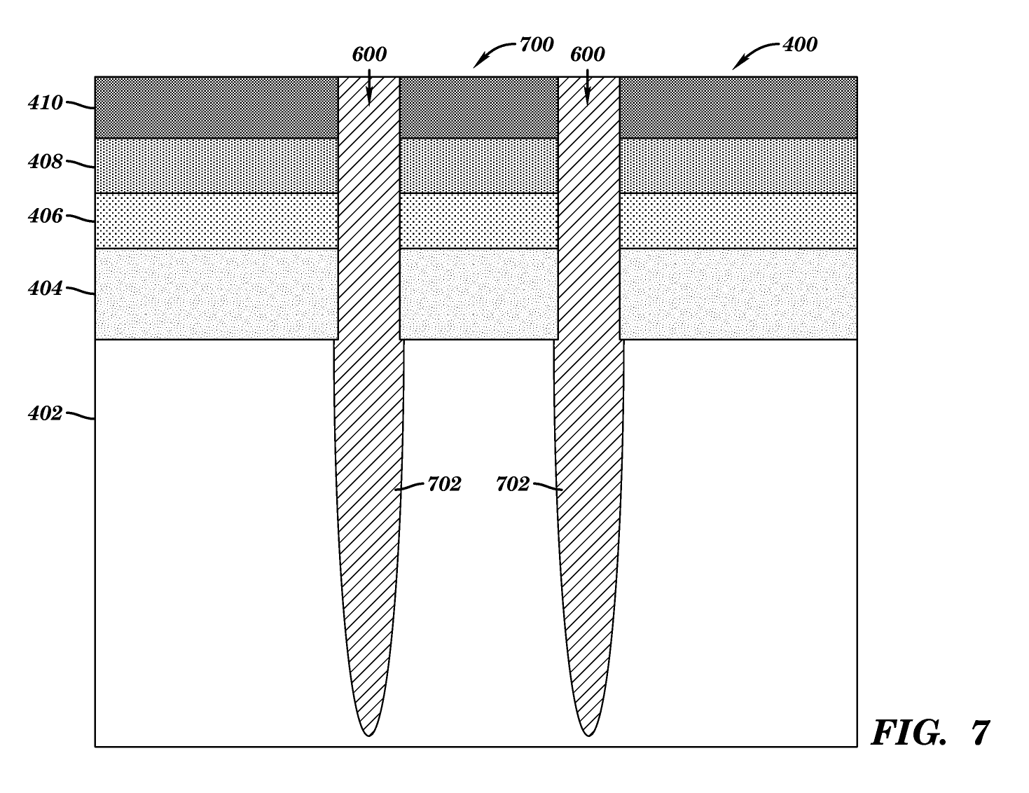

FIG. 7 illustrates a portion of the resultant capacitor 700 following the deposition of a conductive material 702 such as, for example, a polysilicon, or High K material. Prior to the deposition of the conductive material 702, a node dielectric layer (not shown) may be deposited in the trenches 600 that provides boundary between the silicon layer 404 and the conductive material 702. The conductive material 702 may be deposed using a process such as, for example, chemical vapor deposition (CVD) or plasma enhanced chemical vapor deposition (PECVD). The deposition of the conductive material 702 may depose conductive material on the exposed surface of the oxide layer 410. Portions of the conductive material may be removed from the oxide layer 410 using, for example, a planarizing process such as chemical mechanical polishing (CMP) and wet strip.

Though the illustrated embodiments described above include the formation of two trenches, having linear axes arranged in parallel, the methods described above may be used to form any number of trenches in any arrangement such as, a perpendicular or orthogonal arrangement. The methods described above are not limited to the fabrication of capacitive devices, and may be used to form trenches that may be used to fabricate any desired feature or device in a substrate.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A method comprising:
removing an exposed portion of a first portion of a substrate to define a first trench portion partially defined by the first portion of the substrate and expose a second portion of the substrate, the first portion of the substrate disposed on the second portion of the substrate, the second portion of the substrate including an N+ doped silicon material; and
removing a portion the exposed second portion of the substrate with an isotropic etching process to define a second trench portion.

2. The method of claim 1, wherein the isotropic etching process is a transformer coupled plasma (TCP) etching process.

3. The method of claim 2, wherein the TCP etching process includes an etch chemistry of Cl₂ and He materials.

4. The method of claim 3, wherein a ratio of Cl₂ to He materials is about 1 to 1.

5. The method of claim 2, wherein a power used in the TCP etching process is from about 700 W to about 1200 W.

6. The method of claim 2, wherein a pressure used in the TCP etching process is from about 50 millitorr to about 200 millitorr.

7. The method of claim 2, wherein a temperature used in the TCP etching process is from about 50° C. to about 70° C.

8. The method of claim 1, wherein the first portion of the substrate includes a silicon material layer.

9. The method of claim 1, wherein the exposed portion of the first portion of the substrate is removed with an anisotropic etching process.

10. The method of claim 1, further comprising disposing a conductive material in the second trench portion.

11. A method for forming a capacitor device, the method comprising:
removing an exposed portion of a first portion of a substrate to define a first trench portion of a first trench and a first trench portion of a second trench, the first trench portions partially defined by the first portion of the substrate and expose a second portion of the substrate, the first portion of the substrate disposed on the second portion of the substrate, the second portion of the substrate including an N+ doped silicon material;
removing a portion the exposed second portion of the substrate with an isotropic etching process to define a second trench portion of the first trench and a second trench portion of the second trench; and
disposing a conductive material in the second trench portion of the first trench and the second trench portion of the second trench.

12. The method of claim 11, wherein the isotropic etching process is a transformer coupled plasma (TCP) etching process.

13. The method of claim 12, wherein the TCP etching process includes an etch chemistry of Cl₂ and He materials.

14. The method of claim 13, wherein a ratio of Cl₂ to He materials is about 1 to 1.

15. The method of claim 12, wherein a voltage used in the TCP etching process is from about 700 W to about 1200 W.

16. The method of claim 2, wherein a pressure used in the TCP etching process is from about 50 millitorr to about 200 millitorr.

17. The method of claim 12, wherein a temperature used in the TCP etching process is from about 50° C. to about 70° C.

18. The method of claim 11, wherein the first portion of the substrate includes a silicon material layer.

19. The method of claim 11, wherein the exposed portion of the first portion of the substrate is removed with an anisotropic etching process.

20. A capacitor device comprising:
a first trench having a first trench portion partially defined by a first portion of a substrate and a second trench portion partially defined by a second portion of the substrate, the first portion of the substrate including a silicon material layer and the second portion of the substrate including a N+ silicon material, the first trench portion having a substantially uniform width, the second trench portion having a tapered profile, a width of a portion of the second trench portion is greater than the width of the first trench portion;
a second trench arranged substantially parallel to the first trench, the second trench having a first trench portion partially defined by the first portion of the substrate and a second trench portion partially defined by the second portion of the substrate, the first trench portion of the second trench having a substantially uniform width, the second trench portion of the second trench having a tapered profile, a width of a portion of the second trench portion of the second trench is greater than the width of the first trench portion of the second trench; and
a conductive material disposed in the second trench portions of the first trench and the second trench.
